(19) United States
(12) Patent Application Publication
(10) Pub. No.: US 2004/0263213 A1
(43) Pub. Date: Dec. 30, 2004

(54) Current source

(76) Inventors: Oliver Kiehl, Charlotte, VT (US); John A. Fifield, Underhill, VT (US)

Correspondence Address: SLATER & MATSIL, L.L.P., 17950 PRESTON RD, SUITE 1000, DALLAS, TX, 75252-5793, US

(21) Appl. No.: 10/609,248

(22) Filed: Jun. 26, 2003

(51) Int. Cl. H03K 5/22

(52) U.S. Cl. 327/65

(57) ABSTRACT

A constant current source extending the common-mode range comprises a differential pair of transistors connected to a third current source driving transistor. In an embodiment of the invention, the drains of the differential pair are coupled so as to obtain a common-mode voltage. The gate of the third transistor is connected to the drains of the differential pair in order to regulate current flowing through the third transistor. As the voltage decreases at the drain of the third transistor, the gate voltage on the third transistor increases to compensate for the lost voltage on the drain, thereby keeping the current constant even as the third transistor exits the saturation region.

### FIELD OF THE INVENTION

The present invention relates generally to current sources and, in particular, to current sources having extended voltage range.

### BACKGROUND

Constant current sources provide suitable supplies of bias current to analog circuit blocks, including amplifiers and comparators. Interface circuits use comparators to distinguish between logical voltage levels, definitions for which range from SSTL-3 to SSTL-2 and SSTL-1.8. Operation of these interfaces generally assumes a bias voltage at midlevel between ground (VSSQ) and supply (VDDQ). Over the years, the bias voltage of Integrated Circuits (ICs) has dropped from 5V to 1.25V and in the future can be expected to drop to 0.9V. Nevertheless, the threshold voltage for the ICs has remained constant at about 0.5V, leaving very little swing room between the bias voltage and the threshold voltage in which the transistor can produce constant current. At current biasing levels, a device can quickly leave its saturation region and enter its linear region. As the device enters its linear region, the amplification of the amplifier or comparator is degraded.

Although a bias voltage at mid-level presents symmetry to the driving circuits of the interface, it also creates a severe challenge for receiver circuits regarding the required voltage (e.g., common-mode) range. For example, achieving an operating range at a reference voltage of 1.25V, with a signal swing of ±310 mV in an SSTL-2 interface, is difficult. This is true even if designers use NFET technology having low threshold voltages. Achieving an operating range at a reference voltage of 0.9V with an allowable signal swing of ±250 mV in an SSTL-1.8 interface is even more difficult. To address this problem, a wide operating range and NFETS having low threshold voltages are desirable. For example, an existing approach is shown in FIG. 1a, which depicts one of many ways to design a constant current source driving a differential stage. The gate voltage VIREF controls a current source transistor 102. The drain of transistor 102 is connected to the common source of the differential pair of transistors 104 and 106, which in the illustrated embodiment are NFET and, particularly N-MOS, transistors. Nodes CLK and bCLK, in this example, are fully differential input signals to transistors 104 and 106, respectively. Node 108 follows the lower of the input nodes less a threshold voltage. As the voltage at node 108 decreases, it drives transistor 102 out of saturation, thereby reducing the current through transistor 102. Reducing the current flow in transistor 102 causes an increase in the transition delay of the differential stage. This presents a problem, because it is desirable to keep delay constant. However, in this circuit, any change in the current would modulate the delay time. Equally problematic are fluctuations in the current which result in modulating the delay in a differential amplifier.

Extending the operating range of a current source eliminates the need for more complex and expensive solutions, such as adding costly negative supply voltages to extend the voltage range. An unmet need exists for a circuit that can extend the voltage range of a current supply in a simple and inexpensive manner. Furthermore, to avoid changes in current source levels over a wide voltage range, an unmet need exists to provide a current source and gate drive apparatus capable of providing a constant current when the current source transistor is biased in either the saturated or linear regions of operation.

### SUMMARY OF THE INVENTION

The present invention contemplates the extension of a voltage range of a current source, where a gate voltage of a current source transistor is regulated based on the transistor's drain voltage. An embodiment of the present invention accordingly can provide a constant current source even when a current source transistor exits its saturation region.

An embodiment of one aspect of the present invention is directed towards extending the voltage range of a current supply in an IC where the drains of two transistors are connected to each other and a third current source driving transistor has its gate connected to the drains of the two transistors. Further, the drain of the third transistor is connected to the sources of the first two transistors.

In another embodiment, a device is connected to the drain of either the first or second transistor. This device could be a fully differential receiver circuit, a single ended receiver circuit, a differential amplifier circuit, or any other possible circuit that could be connected to an embodiment of the present invention.

In another embodiment of the present invention, a power source is connected to the positive terminal of a current source. The negative terminal of the current source is connected to the drains of two transistors. A third current source driving transistor has its gate connected to the drains of the two transistors. Furthermore, the drain of the third transistor is connected to the sources of the first two transistors.

Another embodiment of the present invention provides a method for extending a voltage range of a current source in an IC, in which the drains of two transistors are connected to each other. The sources of those first two transistors are connected to each other, and the drain of a third current source driving transistor is connected to the sources of the first two transistors. Further, the gate of the third transistor is connected to the drains of the first two transistors.

In another embodiment of the present invention, a circuit is provided for extending a current source's voltage range. The circuit comprises a means for regulating a gate to source voltage using a differential pair and a means for driving current by using a current driving transistor.

According to a further embodiment of the present invention, a current source for use in an integrated circuit to provide an extended voltage range comprises a circuit for measuring a drain voltage using a differential pair, and a circuit for regulating a gate voltage based on the drain voltage measured at the differential pair.

In another embodiment of the present invention, a method for extending a voltage range of a current source in an integrated circuit provides a constant current source in the saturation region of a transistor and maintains that constant current even when the transistor exits the saturation region.

In another embodiment of the present invention, a method for extending a voltage range of a current source in an integrated circuit is provided in which a drain voltage of a transistor is measured and a gate voltage is regulated based on the drain voltage of that transistor.

In another embodiment of the present invention, a method for extending a voltage range of a current source in an integrated circuit is provided which measures a drain voltage using a differential pair and regulates a gate voltage based on the drain voltage measured at the differential pair.

Yet another embodiment of the present invention is a method for extending a voltage range of a current source in an integrated circuit. The method comprises the steps of providing a first transistor and a second transistor, the first transistor having a drain terminal and the second transistor having a gate terminal, measuring the drain terminal voltage of the first transistor, and based on the drain terminal voltage, regulating the gate terminal voltage of the second transistor.

Another embodiment of the present invention is a current source for use in an integrated circuit having an extended voltage range comprising a transistor having a drain characterized by a voltage. In this embodiment, a gate has a voltage that is reactive to the voltage of the drain.

### BRIEF DESCRIPTION OF DRAWINGS

FIG. 1a is a diagram of a conventional differential amplifier.

FIG. 1b is a diagram showing an embodiment of a circuit according to the present invention.

FIG. 2a shows the relationship between drain voltage and gate voltage in a transistor delivering constant current in an embodiment of a circuit according to the present invention.

FIG. 2b shows the relationship between the drain voltage and drain current of a current source transistor utilizing an embodiment of the present invention and a conventional current source circuit.

FIG. 3a shows a conventional differential amplifier used as a receiver.

FIG. 3b is a diagram showing an embodiment of a circuit according to the present invention.

FIG. 3c shows a differential amplifier using a prior art current source.

FIG. 4 shows simulation results of receiver delay using a differential input signal in an embodiment of a circuit according to the present invention in comparison with simulation results of receiver delay using a conventional input circuit.

FIG. 5 shows a comparison similar to that of FIG. 4, but using different values for the circuit components.

### DETAILED DESCRIPTION

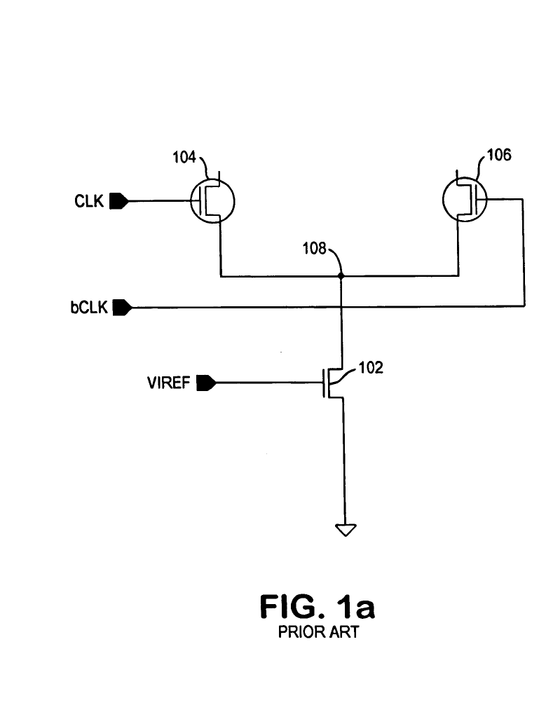

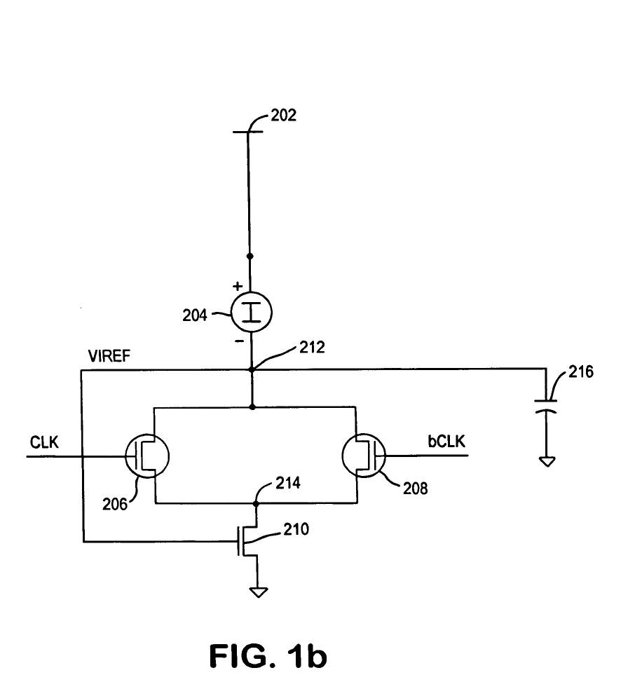

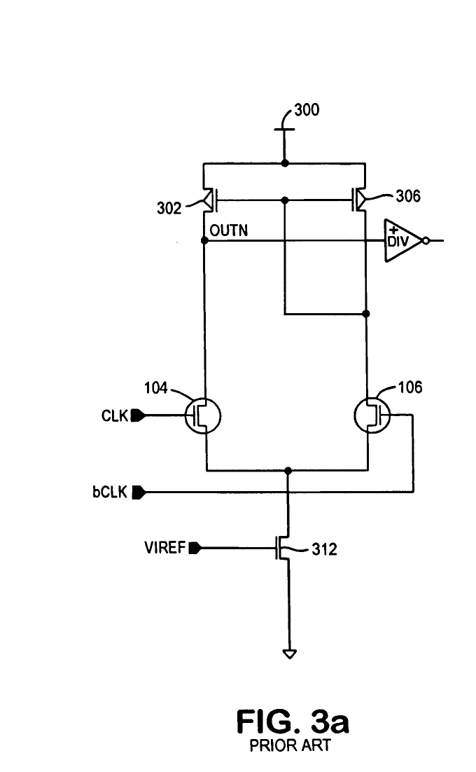

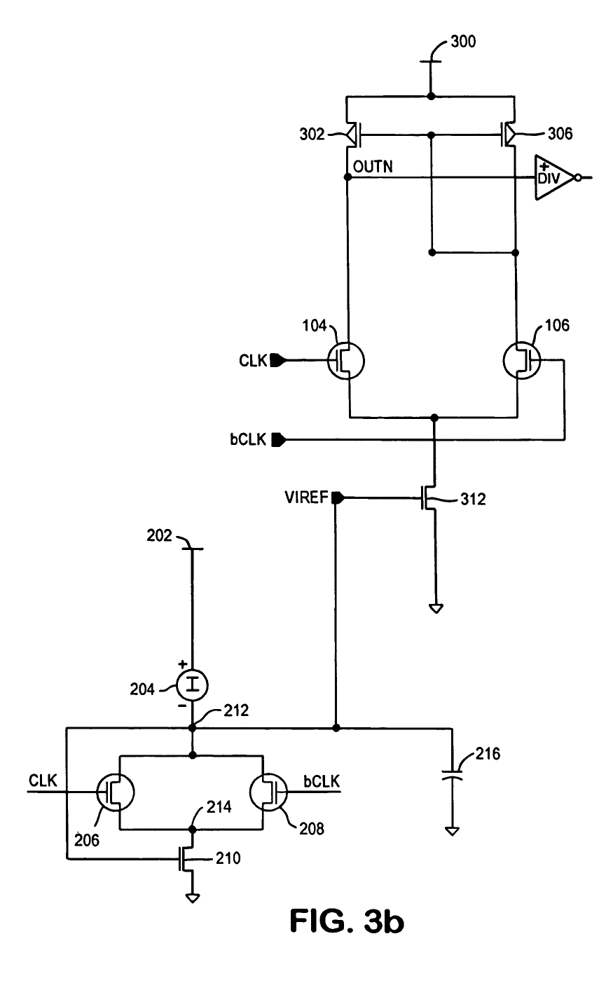

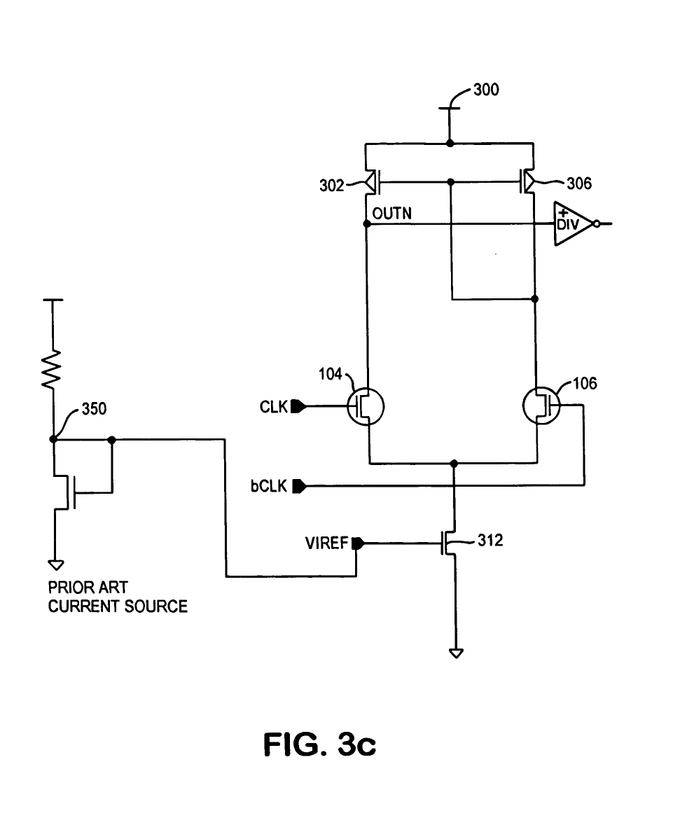

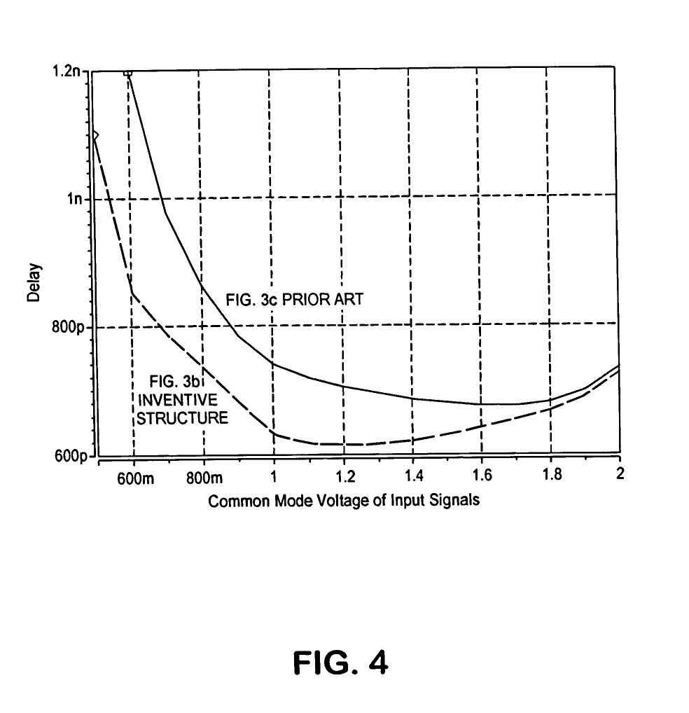

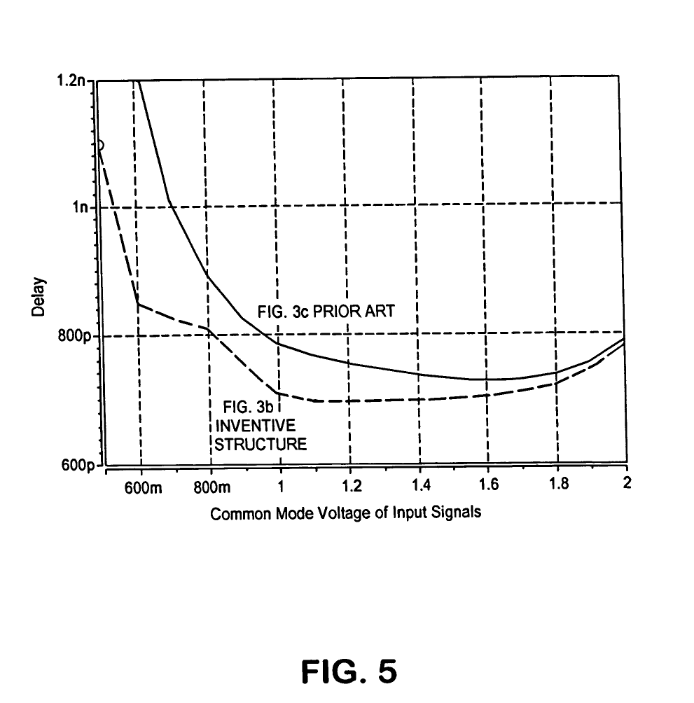

FIG. 1b illustrates an embodiment of a control circuit according to the present invention, based on the receiver circuit of FIG. 1a, and including feedback as further described below. The circuit shown in FIG. 1b generates a VIREF used in a circuit according to the present invention shown in FIG. 3b, as will be described below. In FIG. 1b, power supply 202 is connected to current source 204, which may be an on-chip band gap regulator or other suitable current source. Transistors 206 and 208, which in the illustrated embodiment are NMOS transistors, form a differential pair, the drains of transistors 206 and 208 being connected to each other, as well as to current source 204. In an aspect of the present invention, transistors 206 and 208, have equal width-to-length (W/L) ratios. In the illustrated embodiment, but without limitation, transistors 206 and 208 have W/L ratios of 4 to 0.4. Depending upon the requirements of a specific application, the W/L ratio may be suitably varied.

According to an aspect of the present invention, and in contrast to the conventional circuit of FIG. 1a where the voltage seen by transistor 102 is constant, the gate of NMOS current driving transistor 210 is connected to the drains of transistors 206 and 208 at node 212, enabling the voltage at the gate of current driving transistor 210 to be regulated by the drains of transistors 206 and 208. In an aspect of the present invention, transistor 210 has a W/L ratio of 55 to 0.45. The W/L ratio may be suitably varied depending upon the requirements of a specific application. As further discussed below, in the circuit of FIG. 1b the current through transistor 210 will remain constant even as transistor 210 leaves the saturation region.

The voltage at node 214 follows the lower of the input voltages at transistors 206 and 208, less a threshold voltage of 0.5 volts or lower, resulting in a reduced drain voltage at transistor 210. With CLK and bCLK signals driving the gates of transistors 206 and 208, respectively, a drain voltage is developed on node 214. A resulting gate voltage on transistor 210 allows transistor 210 to conduct at the current level dictated by current source 204, regardless of its drain voltage. In contrast to the conventional circuit of FIG. 1a, in which the lower of CLK and bCLK can be sufficiently low to drive transistor 102 out of saturation and reduce performance of the differential pair of transistors 104 and 106, the current reference level output by current source 204 of the circuit according to the present invention will accordingly flow through transistor device 210 independent of whether transistor 210 is in saturated or linear mode. The gate voltage on 210 adjusts to insure that the reference current of current source 204 will be maintained as the voltage of CLK and bCLK is adjusted.

The response time of a circuit to changes in current flow through the circuit is an important design consideration. The response time of the circuit according to the present invention, as illustrated, can be adjusted by connecting capacitor 216 to node 212. When capacitor 216 has low capacitance, the voltage at node 212 and the gate of transistor 210 will change quickly in response to changes of inputs CLK and bCLK. A low capacitance at 216 may lead to a rapidly varying signal at the gate of transistor 210. On the other hand, when the capacitance of capacitor 216 is high, the voltage at node 212 and gate 210 would have a greater tendency to remain stable during transitions. Therefore, node 212 and the gate at 210 would not reach the correct voltage until the capacitor had charged, leading, in turn, to circuit delay. The value of the capacitance, therefore, is selected to meet the constraints of the resulting circuit's application, taking into account both the character of typical input waveforms and the desired response characteristics.

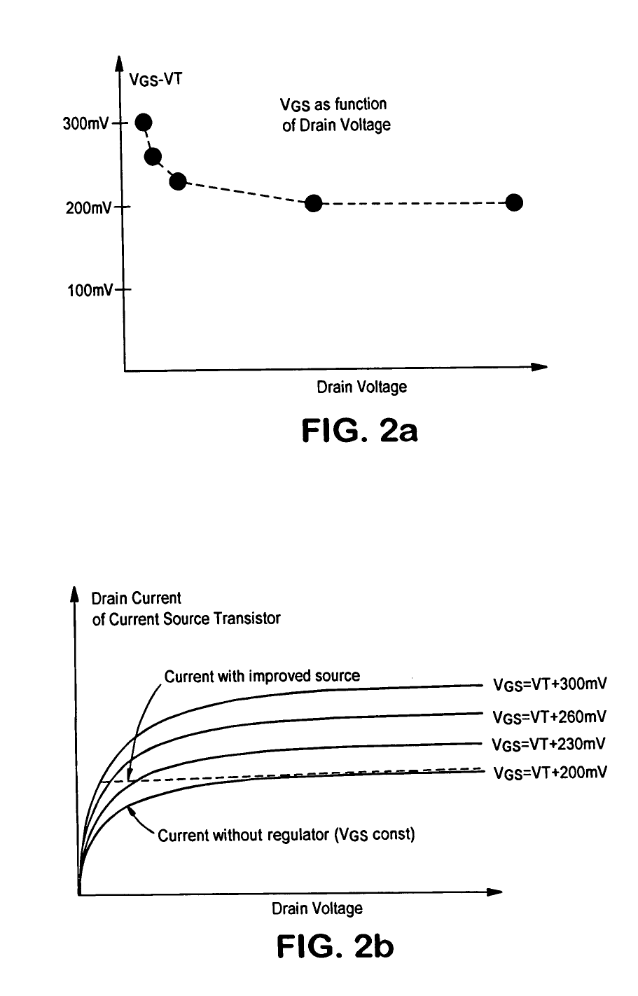

FIGS. 2a and 2b together show the operation of the circuit of FIG. 1b. As illustrated in FIG. 2a, a decreasing drain voltage on transistor 210 causes the gate voltage on 210 to increase. FIG. 2b shows the relationship between the drain current and drain voltage of transistor 210 and that, with this improved source, the current stays constant even as the drain voltage varies. With a decreasing drain voltage, as in FIG. 2a, the gate voltage Vgs (gate to source) increases. FIG. 2b also shows how an increase in the gate voltage Vgs will increase the current through transistor 210. At higher Vgs, a desired current can be sustained at smaller drain voltages. The current therefore remains constant, even when the device leaves saturation and enters the linear region, in which the current flow would normally begin to decrease.

FIG. 3a shows a conventional differential receiver. Voltage source 300 is connected to transistors 302 and 306, which in the illustrated embodiment are PMOS transistors. Transistors 302 and 306 may have W/L ratios which are equal, according to an aspect of the invention, and that are set according to the design constraints of their specific intended application. In one embodiment, but without limitation, they have W/L ratios of 8 to 0.5. The gates of transistors 302 and 306 are also connected to the drain of transistor 306 to create a current mirror. This current mirror forces the amount of current flowing through transistors 302 and 306 to be equal. Transistor 312, which in the illustrated embodiment is an NMOS transistor, acts as a current source for the current mirror and has a gate connected to VIREF.

In conventional circuits, such as in FIG. 3a, the gate of current source transistor 312 or its equivalent is connected to a stable voltage that maintains the source-drain current at a desired level, so long as transistor 312 remains biased in the saturated region. As lower-voltage technologies are developed, the DC operating points of differential amplifiers are diminishing to the point where it is difficult to maintain a current source that is coupled to a differential pair biased in its saturated region. For example, in a 1V technology with 200 mv threshold voltages, an input reference level of 0.5V will be typically used. To maintain conduction of differential devices such as transistors 104 and 106 in FIG. 1a, and analogous transistors described with reference to the embodiments in FIGS. 1b and 3a-3c, their source nodes are preferably 0.5V−0.2V=0.3V. This requires that the drain voltage of the current source be at 0.3V. At drain voltages lower than 0.3V on current source transistor 312, the current begins to fall off as transistor 312 enters the linear range of operation. This drop in current will result in undesirable changes to propagation delay through the differential amplifier.

Referring to FIG. 3b, the structure in FIG. 3a has been adapted to provide a constant current source for a typical differential amplifier in an embodiment of an aspect of the present invention. This occurs by coupling the circuit shown in FIG. 1b to the VIREF shown in FIG. 3a at node 212. In FIG. 3b, a constant current source level 204 has been derived from an on-chip bandgap reference or by other convenient methods and is used to supply a reference current into differential pair of transistors 206 and 208. With CLK and bCLK signals driving the gates of transistors 206 and 208 respectively, a drain voltage is developed on node 214. A gate voltage on device 210 will result which will allow device 210 to conduct at the current level dictated by current reference 204, regardless of the drain voltage of device 210. The current reference level output by 204 will flow through device 210 independent of whether device 210 is in saturated or linear mode, and the gate voltage on 210 will adjust to insure the reference current will flow as the voltage of CLK and bCLK is adjusted.

The voltage level on the gate of device 210, VI REF, is used to gate the current source transistor 312 in the differential amplifier formed by transistors 104, 106, 306 and 302. The matching of the W/L ratios between transistors 104, 106 and 302,306, are important in determining the amount of current flow through the circuit. As inputs CLK and bCLK swing around a voltage point, the VIREF level will be adjusted by the inventive structure to maintain a constant current in current source transistor 312. Using the improved current source described above, propagation delay through the differential amplifier is held more constant, and particularly as the voltage drops, current is maintained and propagation delay time does not increase.

As shown in FIG. 3c, a prior art current source can be connected to input VIREF. Nevertheless, as will be shown, the delay of this circuit is greater and less predictable than the delay that results from the circuit in FIG. 3b.

FIG. 4 shows the simulation results of receiver delay for a differential input signal from a circuit according to the present invention in comparison with a circuit according to the prior art. The lower curve of FIG. 4 represents the receiver delay for the embodiment of a circuit according to the present invention of FIG. 3b. The control voltage 212 is connected to the gate of current source transistor 312 such that constant current will be supplied to differential transistors 104 and 106. The circuit in FIG. 3b sustains the same current flow even when current source transistor 312 exits the saturation region. This is because the gate voltage of transistor 312 in FIG. 3b is connected to node 212 which, as stated earlier, increases in voltage as the drain voltage of the current driving transistor decreases. Thus, even when the voltage at the drain of transistor 312 decreases, the gate voltage of transistor 312 will increase to compensate by action of the control circuit according to FIG. 1b. The upper curve of FIG. 4 represents the receiver delay for the circuit in FIG. 3c. FIG. 3c has a prior art configuration for a current source. FIG. 4 demonstrates that compared to a conventional prior art current source, the current driving transistor 312 which is connected to an embodiment of a circuit according to the present invention has a signal whose receiver delay is diminished and more constant over a wider voltage range.

In the example of FIG. 4, capacitor 216 has a capacitance of zero. FIG. 5 is an analysis of the same circuit as in FIG. 4 and illustrates the same comparison of delay between FIGS. 3b and 3c, but uses a capacitor value of 1 pF for capacitor 216.

The current source according to the present invention is useful in single-ended IC applications. Referring to the embodiment shown in FIG. 1b, for example, a single-ended application is created when the gate terminals of transistors 206 and 208 are tied to node 212. In a single-ended system, a lower capacitance on capacitor 216 is recommended for improved symmetry between rising and falling edges.

This technique has been demonstrated using NFET current sources and differential pairs for purposes of illustration, but any suitable transistors could be used. For example, various embodiments of the circuits and methods according to the present invention can be created wherein PFET current sources and, or PFET differential pairs are used.

While the invention has been particularly shown and described with reference to particular embodiments, those skilled in the art will understand that various changes in form and details may be made without departing form the spirit and scope of the invention as set forth in the appended claims.

What is claimed is:

1. A current source for use in an integrated circuit providing an extended voltage range, comprising:
a first transistor having first and second non-gate terminals;
a second transistor having first and second non-gate terminals, the first non-gate terminal coupled to the first non-gate terminal of the first transistor; and
a bias generator having a non-gate terminal coupled to the second non-gate terminals of the first and second transistors, the bias generator further having a gate terminal coupled to the first non-gate terminals of the first and second transistors.

2. The current source circuit according to claim 1, wherein the voltage range comprises a common mode range.

3. The current source circuit according to claim 1, wherein:
the second non-gate terminals of the first and second transistors comprise sources.

4. The current source circuit according to claim 1, wherein:
at least one of the first transistor, second transistor, and bias generator comprises an NMOS transistor.

5. The current source circuit according to claim 1, wherein the bias generator comprises a transistor.

6. The current source circuit according to claim 1, further comprising:
a capacitor coupled to the first non-gate terminals of the first and second transistors.

7. The current source circuit according to claim 6, wherein:
the capacitor has capacitance less than or equal to approximately 1 pF.

8. The current source according to claim 6, wherein:
the capacitor has capacitance less than or equal to approximately 1 fF.

9. The current source according to claim 1, wherein the first and second transistors are coupled in parallel.

10. A method of extending a voltage range of a current source for differential amplifiers and comparators in an integrated circuit, the method comprising the steps of:
providing a first transistor, a second transistor, and a third transistor, the first and second transistors each having a drain and a source, the third transistor having a gate and a drain;
connecting the drain of the first transistor to the drain of the second transistor;
connecting the source of the first transistor to the source of the second transistor;
connecting the gate of the third transistor to the drains of the first and second transistors; and
connecting the drain of the third transistor to the sources of the first and second transistors.

11. The method according to claim 10, wherein the voltage range comprises a common-mode range.

12. A current source for use in an integrated circuit providing an extended voltage range, comprising:
a voltage source;
a current source having a positive and negative terminal, wherein the positive terminal is connected to the voltage source;
a first NMOS transistor having a source terminal and drain terminal, the drain terminal connected to the negative terminal of the current source;
a second NMOS transistor having a source terminal and drain terminal, the drain terminal of the second NMOS transistor connected to the drain terminal of the first NMOS transistor, the source terminal of the second NMOS transistor connected to the source terminal of the first NMOS transistor; and
a third NMOS transistor having a gate terminal and drain terminal, the drain terminal of the third NMOS transistor connected to the source terminals of the first and second NMOS transistors, the gate terminal of the third NMOS transistor connected to the drains of the first and second NMOS transistors.

13. The current source according to claim 12, wherein the voltage range comprises a common-mode range.

14. The current source circuit according to claim 12, further comprising:
a capacitor connected to the drain terminals of the first and second NMOS transistors.

15. A current source for use in an integrated circuit providing an extended common-mode range, comprising:
means for regulating a gate-to-source voltage using a differential pair; and
coupled to the regulating means, a current driving transistor.

16. A constant current source for use in an integrated circuit extending a voltage range, comprising:
a first transistor having first and second non-gate terminals;
a second transistor having first and second non-gate terminals, the first non-gate terminal coupled to the first non-gate terminal of the first transistor;
a bias generator having a non-gate terminal coupled to the second non-gate terminals of the first and second transistors, the bias generator further having a gate terminal coupled to the first non-gate terminals of the first and second transistors; and
a fully differential receiver connected to at least one of the first non-gate terminals of the first and second transistor.

17. The current source according to claim 16, wherein the voltage range comprises a common-mode range.

18. The current source according to claim 16, wherein:
the first and second transistors are coupled in parallel.

19. A constant current source for use in an integrated circuit extending voltage range in a single ended receiver circuit, comprising:
a first transistor having first and second non-gate terminals and a gate terminal;
a second transistor having first and second non-gate terminals and a gate terminal, the first non-gate terminal of the second transistor coupled to the first non-gate terminal of the first transistor, and the gate terminal of the second transistor coupled to the gate terminal of the first transistor, the gate terminals of the first and second transistors coupled to the first non-gate terminal of the first and second transistors;
a bias generator having a non-gate terminal coupled to the second non-gate terminals of the first and second transistors, the bias generator further having a gate terminal coupled to the first non-gate terminals of the first and second transistors; and
a receiver coupled to at least one of the first non-gate terminals of the first and second transistors.

20. The current source circuit according to claim 19, wherein the voltage range comprises a common-mode range.

21. The current source circuit according to claim 19, wherein the first and second transistors are coupled in parallel.

22. A constant current source for use in an integrated circuit to extend a voltage range of a differential amplifier circuit, comprising:
a first transistor having first and second non-gate terminals;
a second transistor having first and second non-gate terminals, the first non-gate terminal coupled to the first non-gate terminal of the first transistor;
a bias generator having a non-gate terminal coupled to the second non-gate terminals of the first and second transistor, the bias generator further having a gate terminal coupled to the first non-gate terminals of the first and second transistors; and
a differential amplifier coupled to at least one of the first non-gate terminals of the first and second transistors.

23. The current source according to claim 22, wherein the voltage range comprises a common-mode range.

24. The current source circuit according to claim 22, wherein the first and second transistors are coupled in parallel.

25. A method for extending a voltage range of a current source in an integrated circuit, the method comprising the steps of:
providing a first transistor and a second transistor, the first transistor having a drain terminal and the second transistor having a gate terminal;
measuring a drain terminal voltage of the first transistor; and,
based on the drain terminal voltage, regulating a gate terminal voltage of the second transistor.

26. The method according to claim 25, wherein the voltage range comprises a common-mode range.

27. The method according to claim 25, further comprising:
a third transistor having a drain terminal;
measuring a drain terminal voltage of the third transistor; and
based on the drain terminal voltage, regulating a gate terminal voltage of the second transistor.

28. A current source for use in an integrated circuit providing an extended voltage range, comprising:
a circuit for measuring a drain voltage using a differential pair; and
a circuit for regulating a gate voltage based on the drain voltage measured at the differential pair.

29. The current source according to claim 28, wherein the voltage range comprises a common-mode range.

30. A method of extending a voltage range of a current source in an integrated circuit, the method comprising the steps of:
providing a constant current source in a saturation region of a transistor; and
maintaining the constant current if the transistor exits the saturation region.

31. The method according to claim 30 wherein the constant current is maintained by increasing the gate voltage of the transistor when the transistor leaves the saturation region.

32. The method according to claim 30, wherein the voltage range comprises a common-mode range.

33. A method for extending a voltage range of a current source in an integrated circuit, the method comprising the steps of:
measuring a drain voltage of a transistor; and
regulating a gate voltage based on the drain voltage of that transistor.

34. The method according to claim 33 wherein the gate voltage is regulated such that the current remains constant even if the transistor is not in saturation.

35. A method for extending a voltage range of a current source in an integrated circuit, the method comprising the steps of:
measuring a drain voltage using a differential pair; and
regulating a gate voltage based on the drain voltage measured at the differential pair.

36. The method according to claim 35, wherein the voltage range comprises a common-mode range.

37. A current source for use in an integrated circuit having an extended voltage range comprising:
a transistor:
having a drain characterized by a voltage; and
a gate having a voltage that is reactive to the voltage of the drain.

38. The current source according to claim 37, where the gate voltage is regulated based on the drain voltage.

39. The current source according to claim 37, wherein the gate is not directly coupled to the drain.

40. The current source according to claim 37, wherein the gate is directly coupled to the drain.

41. The current source according to claim 37, wherein the voltage range comprises a common-mode range.
